(19) United States
(12) Patent Application Publication
(10) Pub. No.: US 2008/0236654 A1
(43) Pub. Date: Oct. 2, 2008

(54) WINDOW CONSTRUCTION COMBININB NiMH TECHNOLOGY AND SOLAR POWER

(75) Inventors: Nicolas J. Pietrangelo, Spring Lake, MI (US); Thomas J. Moran, Troy, MI (US)

Correspondence Address: PRICE HENEVELD COOPER DEWITT & LITTON, LLP, 695 KENMOOR, S.E., P O BOX 2567, GRAND RAPIDS, MI, 49501, US

(73) Assignee: TSNERGY, Inc., Troy, MI (US)

(21) Appl. No.: 12/046,618

(22) Filed: Mar. 12, 2008

Related U.S. Application Data
(60) Provisional application No. 60/908,281, filed on Mar. 27, 2007.

(51) Int. Cl. H01L 31/048; E04H 14/00

(52) U.S. Cl. 136/251; 52/173.3

(57) ABSTRACT

A building has a plurality of rooms, each including an exterior window construction incorporating thin-film photovoltaic system for converting solar energy into electrical energy. A controller in each room is operably connected to the photovoltaic system and to the building's power grid and to any electricity-using devices in the rooms. The controller is programmed to provide a self-sustaining modular system where, when the building power grid loses power, each room becomes an independently self-powered system and has battery recharging capability. The window construction includes a mullion, a thin-film photovoltaic system incorporating a glass pane supported by the mullion that permits visibility through the glass pane, and a Nickel-Metal-Hydride (NiMH) battery positioned in the mullion and operably connected to the photovoltaic film for recharging from electricity generated by solar power on the photovoltaic film.

This application claims benefit under 35 U.S.C. § 119(e) of provisional application Ser. No. 60/908,281, filed Mar. 27, 2007, entitled WINDOW CONSTRUCTION COMBINING NiMH TECHNOLOGY AND SOLAR POWER, the entire contents of which are incorporated herein in its entirety.

### BACKGROUND

The present invention relates to a window construction combining Nickel-Metal-Hydride (NiMH) technology and solar power. Also, the present invention relates to a building system where window constructions incorporating NiMH battery technology and solar electrical power generation are combined to provide a self-sustaining modular system with each exterior room of a building being potentially independently self-powered and where each room has battery recharging capability.

Winarski U.S. Pat. No. 6,688,053 discloses a double-pane window that generates solar-powered electricity and that, through the use of mirrors, also maintains visibility through the window. Further, Winarski '053 discloses that a DC to AC converter can be used, and that the circuit can be connected to the building's power grid. However, Winarski does not address an overall system with modularly constructed room systems that are configured for self-sufficiency and self-functioning in the event of a building power outage. Nor does Winarski address recharging of batteries by the solar power-generating system, nor the need to reduce a risk of overheating and fire during battery recharging. For example, rechargeable lithium ion batteries, which are widely used in high-current-draw applications such as for computers and hand-held devices, may overheat and cause a fire. As a result, there have been several major recalls and safety concerns in their use. It is noted that a fire in a building can have serious consequences, particularly if the battery is stored within a building component such as a mullion of a window.

Fronek U.S. Pat. No. 6,646,196 and Bower U.S. Pat. No. 6,750,391 also disclose window structures of interest with photovoltaic panels interconnected to a circuit including items such as a charge controller, storage batteries, a DC to AC inverter, switches, and fuses for power control. However, Fronek and Bower also do not address an overall system with modularly constructed room systems that are configured for self-sufficiency and self-functioning in the event of a building power outage. Nor do they address recharging of batteries by the solar power-generating system, nor the need to reduce a risk of overheating and fire during battery recharging.

Nickel-Metal-Hydride (NiMH) technology is rapidly advancing. However, there is an absence of products and systems applying this technology to building constructions. In particular, there is a need for building constructions that take advantage of the properties of NiMH technology for optimal benefits in buildings.

### SUMMARY OF THE PRESENT INVENTION

In one aspect of the present invention, a building construction includes a window frame including a mullion and a glass pane supported by the mullion, and a thin-film photovoltaic system covering at least part of the glass pane and permitting visibility through the glass pane. The construction further includes a circuit incorporating a Nickel-Metal-Hydride (NiMH) battery positioned in the mullion and operably connected to the photovoltaic system for recharging from electricity generated by solar power on the photovoltaic system.

In another aspect of the present invention, a building system includes a plurality of rooms each including an exterior window construction incorporating a thin-film photovoltaic system for converting solar energy into electrical energy and a battery for storing the electrical energy. A building power grid includes a power line extended to each of the plurality of rooms. A plurality of electricity-connecting devices are located in each of the plurality of rooms including a DC battery-type connecting outlet and an AC type connecting outlet for connecting to a DC power-using device and an AC power-using device. A controller independently controls a flow of electrical power with each room and is operably connected by a circuit to the photovoltaic system and to the building power grid and to the plurality of electricity-using devices. The controller is programmed to provide a self-sustaining modular system where, when the building power grid loses power, each one of the rooms becomes an independently self-powered system and where each room has battery recharging capability.

An object of the present system is to provide a building that is a “building power plant,” with modular distributed energy generation, where the controller is configured to export energy from the modular systems in each room into the building power grid (and exported from the building into community power systems), and where the controller is configured and programmed to import energy from the building power grid into the modular systems in each room (such as during a series of dark, cloudy days). Thus, an uninterruptible supply of energy is provided to each individual room, in both AC and DC systems. Further, the energy systems of each room add an energy storage capability to the building power grid, further assuring that the supply of energy is uninterruptible, yet efficient in collection and distribution.

These and other aspects, objects, and features of the present invention will be understood and appreciated by those skilled in the art upon studying the following specification, claims, and appended drawings.

### BRIEF DESCRIPTION OF DRAWINGS

FIG. 1 is a perspective view of a window construction embodying the present invention.

FIGS. 2-3 are a perspective and a cross-sectional view of the center mullion in the window construction of FIG. 1.

FIG. 4 is a plan view of the window construction of FIG. 1, partially broken away to show internal wiring and components.

FIG. 5 is a perspective view of three rooms of a building, each incorporating the window construction of FIG. 1 and including various building fixtures and furniture, and each further being outfitted with an electrical control system operably connected to the associated solar powered system and to the building power system.

FIG. 6 is a schematic view of the electrical control system of FIG. 5.

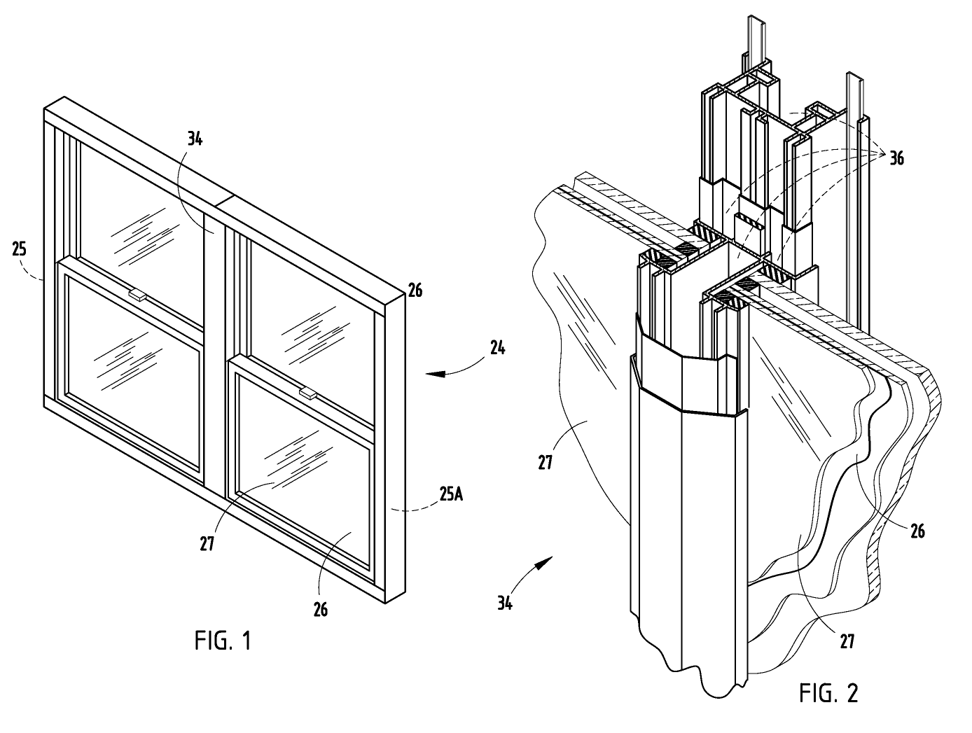

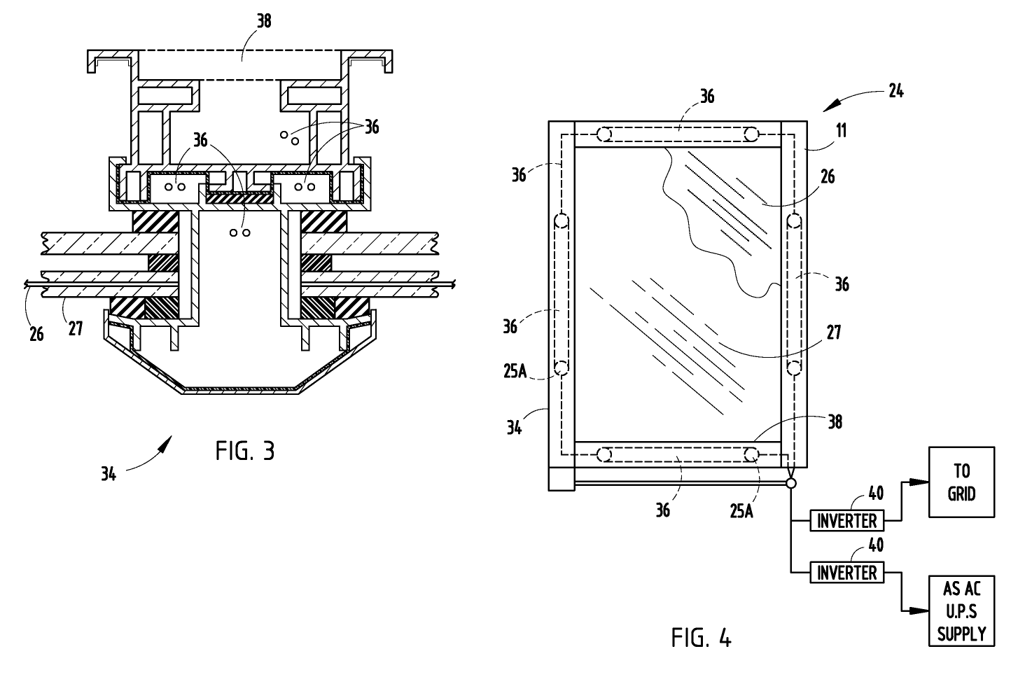

### DETAILED DESCRIPTION OF PREFERRED EMBODIMENTS

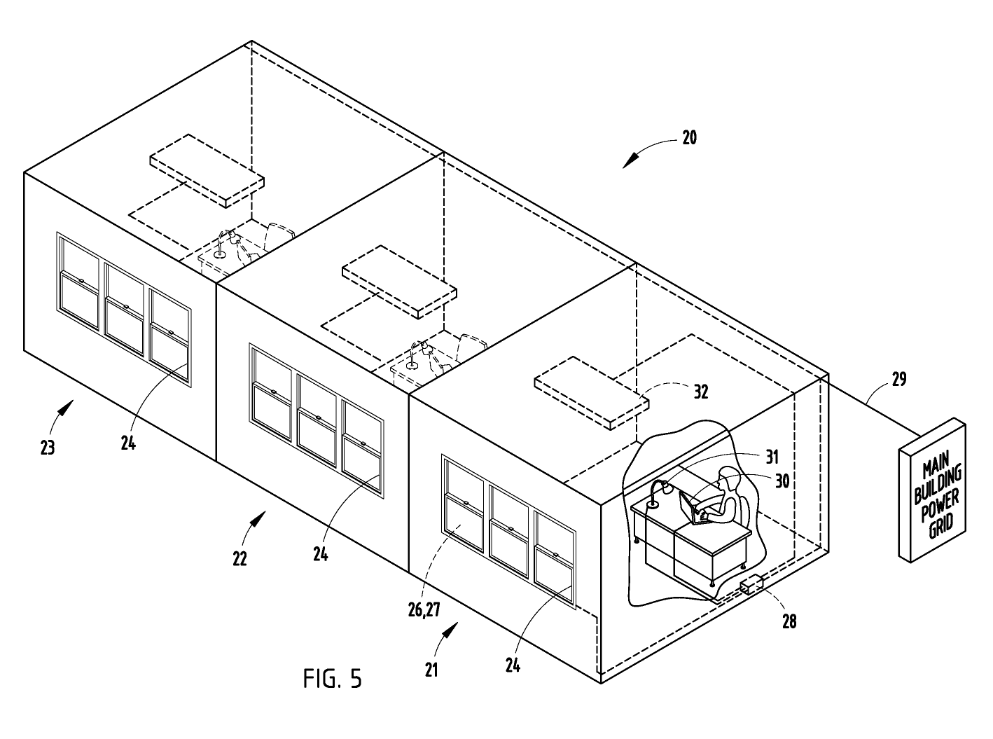

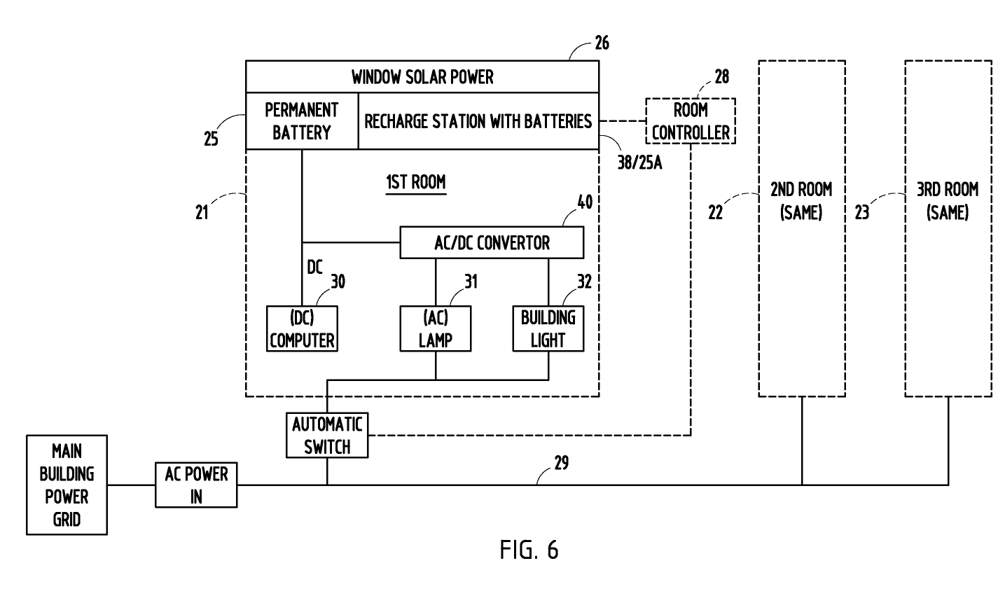

A building 20 has a plurality of rooms, three rooms 21, 22, 23 being illustrated in FIG. 5. Each room includes an exterior window construction 24 incorporating a permanent NiMH battery 25, a recharge station 38 for recharging NiMH batteries 25A, and a thin-film photovoltaic system 26 (which includes a glass pane 27) for converting solar energy into electrical energy for storage in the battery 25. The batteries 25 and 25A are preferably NiMH batteries to minimize risk of overheating and fire. A controller 28 in each room is operably connected to the photovoltaic system 26 and through an automatic switch to the building's power grid 29 and to any electricity-using devices (such as illustrated lap top computer 30, desk light 31, and overhead building light 32) in the rooms. The controller 28 is programmed to provide a self-sustaining modular power system to each room where, when the building power grid 29 loses power, each room becomes an independently self-powered system and has battery recharging capability. The window construction 24 (FIG. 4) includes a mullion 34 forming part of the window frame 41 described below which supports the glass pane 27, with the thin-film photovoltaic system 26 (with glass pane 27, inside or outside surface) but permitting visibility through the glass pane 27. The photovoltaic system 26 is connected with wires 36 to permanent Nickel-Metal-Hydride (NiMH) batteries 25 positioned in the mullion 34 and window frame 41, and further includes the recharge stations 38 for receiving NiMH batteries 25 for recharge, and further includes switches 39, and AC-to-DC inverter 40 all interconnected to the controller 28 for controlled independent operation of the system even if the building's power grid 29 loses power.

FIG. 4 discloses the window construction 24 with integral solar-powered electrical generation system where the window system includes a window frame 41 and interior glass 42. A thin film 43, such as microcrystalline, is deposited on the window glass 42 that allows light to pass through but also provides shading (if desired). It is contemplated that other thin film systems can be used, such as a thin film CdTe system, a thin film amorphous or microcrystalline, a thin film dye-sensitized organic system, or a thin film copper idmium disalinide system. Preferably, the film 43 does not darken in order to maintain optimal visual (see-through) properties. An electrical circuit 44 is positioned in the window frame 41 and includes storage cells/permanent batteries 25 connected by wiring 46 as well as the recharge stations 38. Locations are provided for receiving batteries 25A such as “C” or “D” cell batteries for recharge. The illustrated system 44 is divided into multiple grids 1, 2, 3, and 4 which can be tapped for providing a 12 volt system, or connected in combination for providing 24 volt, 36 volt, or 48 volt systems. The present system can be used to recharge batteries or can be connected to supply supplemental electrical power to the building power grid 29 (or house electrical system), such as for operating lights or a 110 volt AC system.

The present system, when installed in rooms of a building, basically turns the building into a “building power plant,” with modular distributed energy generation, where the controller is configured and programmed to cause energy to be exported from the modular systems in each room into the building power grid (and exported from the building into community power systems) (such as during a sunny weekend day when there is low power usage in the room), and where the controller is configured and programmed to import energy from the building power grid into the modular systems in each room (such as during a series of dark, cloudy days). Thus, an uninterruptible supply of energy provides to each individual room, in both AC and DC type systems. Further, the energy systems of each room add an energy storage capability to the building power grid, further assuring that the supply of energy is uninterruptible, yet efficient in collection and distribution.

It is to be understood that variations and modifications can be made on the aforementioned structure without departing from the concepts of the present invention, and further it is to be understood that such concepts are intended to be covered by the following claims unless these claims by their language expressly state otherwise.

The embodiments of the invention in which an exclusive property or privilege is claimed are defined as follows:

1. A construction comprising:
a window frame including a mullion;
a thin-film photovoltaic system incorporating a glass pane supported by the mullion and covering at least part of the glass pane and permitting visibility through the glass pane; and
a circuit including a Nickel-Metal-Hydride (NiMH) battery positioned in the mullion and operably connected to the photovoltaic system for recharging from electricity generated by solar power on the photovoltaic system.

2. The construction defined in claim 1, wherein the battery is removable and rechargeable.

3. The construction defined in claim 1, wherein the circuit includes switches and is configured to provide different voltages such as 12 v, 24 v, and 36 v depending on the number and type of batteries.

4. The construction defined in claim 1, wherein the circuit includes an AC-to-DC and DC-to-AC converter.

5. The construction defined in claim 1, wherein the circuit includes a controller for controlling electrical power from the photovoltaic system and from a building power grid.

6. A building system comprising:
a plurality of rooms each including an exterior window construction incorporating thin-film photovoltaic system for converting solar energy into electrical energy and a battery for storing the electrical energy;
a building power grid including a power line extended to each of the plurality of rooms;
a plurality of electricity-connecting devices in each of the plurality of rooms including a DC battery-type connecting outlet and an AC type connecting outlet for connecting to a DC power-using device and an AC power-using device; and
a controller associated to independently control flow of electrical power with each room and that is operably connected by a circuit to the photovoltaic system and to the building power grid and to the plurality of electricity-using devices, the controller being programmed to provide a self-sustaining modular system where, when the building power grid loses power, each one of the rooms becomes an independently self-powered system and where each room has battery recharging capability.

7. The system defined in claim 6, wherein the battery is removable and rechargeable.

8. The system defined in claim 6, wherein the circuit includes switches and is configured to provide different voltages such as 12 v, 24 v, and 36 v depending on the number and type of batteries.

9. The system defined in claim 6, wherein the circuit includes an AC-to-DC and DC-to-AC converter.

10. The system defined in claim 6, wherein the controller is programmed to export energy from the photovoltaic system to the building power grid, as well as to import energy from the building power grid to the photovoltaic system as needed.
